(19) United States
(12) Patent Application Publication
(10) Pub. No.: US 2020/0185640 A1
(43) Pub. Date: Jun. 11, 2020

(54) DISPLAY PANEL AND A DISPLAY DEVICE

(71) Applicant: BOE Technology Group Co., Ltd., Beijing (CN)

(72) Inventor: Hao Gao, Beijing (CN)

(21) Appl. No.: 16/422,514

(22) Filed: May 24, 2019

(30) Foreign Application Priority Data
Dec. 7, 2018 (CN) 201822058113.3

(51) Int. Cl. H01L 51/52; G09G 3/3208

(52) U.S. Cl. CPC H01L 51/5237; G09G 3/3208

(57) ABSTRACT

A display panel and a display device are disclosed, the display panel including: a base substrate and a light-emitting device thereon; and an encapsulating structure on a side of the light-emitting device facing away from the base substrate and completely covering the light-emitting device; an optical membrane layer between the encapsulating structure and the light-emitting device; the encapsulating structure includes a first inorganic encapsulating membrane above the light-emitting device on a side of the optical membrane layer facing away from the base substrate and a second inorganic encapsulating membrane on a side of the first inorganic encapsulating membrane facing away from the base substrate; the first inorganic encapsulating membrane has a refractive index lower than that of the second inorganic encapsulating membrane and the optical membrane layer; or the first inorganic encapsulating membrane has a refractive index higher than that of the second inorganic encapsulating membrane and the optical membrane layer.

### CROSS-REFERENCE TO RELATED APPLICATION

The present disclosure claims the benefit of Chinese Patent Application Invention No. 201822058113.3 filed on Dec. 7, 2018 in the China National Intellectual Property Administration, the whole disclosure of which is incorporated herein by reference.

### BACKGROUND

### Field

Embodiments of the present disclosure generally relate to the technical field of display technology, and in particular, to a display panel and a display device.

### Description of the Related Art

There is a development tendency of gradually replacing a rigid OLED with a flexible OLED, due to its flexible and bendable properties. However, in a process that a rigid encapsulating structure for OLED which has a glass packaging as a main packaging/encapsulating manner gradually transits to a flexible encapsulating structure for OLED which has a membrane packaging as a main packaging/encapsulating manner, due to difference between these two encapsulating structures, then a decrease in a light extraction efficiency of original OLED device comes up to about 20%.

### SUMMARY

The embodiments of the present disclosure have been made to overcome or alleviate at least one aspect of the above mentioned disadvantages and/or shortcomings in the prior art, by providing a display panel and a display device, with a first inorganic encapsulating membrane and a second inorganic encapsulating membrane being provided on an optical membrane layer.

Following technical solutions are adopted in exemplary embodiments of the invention.

According to one aspect of embodiments of the disclosure, there is provided a display panel, comprising: a base substrate; a light-emitting device on the base substrate; and an encapsulating structure on a side of the light-emitting device facing away from the base substrate and completely covering the light-emitting device; an optical membrane layer is provided between the encapsulating structure and the light-emitting device; the encapsulating structure comprises: a first inorganic encapsulating membrane above the light-emitting device and on a side of the optical membrane layer facing away from the base substrate, and a second inorganic encapsulating membrane on a side of the first inorganic encapsulating membrane facing away from the base substrate; and the first inorganic encapsulating membrane has a refractive index lower than that of the second inorganic encapsulating membrane and that of the optical membrane layer; or the first inorganic encapsulating membrane has a refractive index higher than that of the second inorganic encapsulating membrane and that of the optical membrane layer.

According to an exemplary embodiment of the present disclosure, the refractive index of the first inorganic encapsulating membrane ranges between about 1.4 and about 1.6.

According to an exemplary embodiment of the present disclosure, the first inorganic encapsulating membrane is formed by a material comprising SiOx.

According to an exemplary embodiment of the present disclosure, the first inorganic encapsulating membrane has a thickness ranging between about 40 nm and about 120 nm.

According to an exemplary embodiment of the present disclosure, the refractive index of the second inorganic encapsulating membrane ranges between about 1.75 and about 1.9.

According to an exemplary embodiment of the present disclosure, the second inorganic encapsulating membrane is formed by a material comprising SiNxOy.

According to an exemplary embodiment of the present disclosure, the second inorganic encapsulating membrane has a thickness ranging between about 800 nm and about 1000 nm.

According to an exemplary embodiment of the present disclosure, in response to a condition that the first inorganic encapsulating membrane has its refractive index lower than that of the second inorganic encapsulating membrane and that of the optical membrane layer, the refractive index of the second inorganic encapsulating membrane is larger than or equal to the refractive index of the optical membrane layer.

According to an exemplary embodiment of the present disclosure, in response to a condition that the first inorganic encapsulating membrane has its refractive index higher than that of the second inorganic encapsulating membrane and that of the optical membrane layer, the refractive index of the second inorganic encapsulating membrane is smaller than or equal to the refractive index of the optical membrane layer.

According to an exemplary embodiment of the present disclosure, the encapsulating structure further comprises: an organic encapsulating membrane on a side of the second inorganic encapsulating membrane facing away from the base substrate; and a third inorganic encapsulating membrane on a side of the organic encapsulating membrane facing away from the base substrate.

According to another aspect of the exemplary embodiment of the present disclosure, there is provided a display device, comprising any one display panel as provided in above technical solutions.

### BRIEF DESCRIPTION OF THE DRAWINGS

The drawings are used to provide a further understanding of technical solutions of the present disclosure, and constitute a part of the specification, and they are provided to explain the technical solutions of the present disclosure with reference to the embodiments of the present disclosure, but do not form a limitation to the technical solutions of the present disclosure.

FIG. 1 illustrates a structural schematic view of a flexible display panel according to embodiments of the disclosure;

FIG. 2 illustrates a structural schematic view of a display device according to embodiments of the disclosure.

### DETAILED DESCRIPTION

Technical solutions of embodiments of the present disclosure will be described clearly and completely with reference to drawings of the embodiments in the present disclosure. It is apparent that the described embodiments are only part of embodiments of the present disclosure, rather than all of the embodiments. On the basis of the embodiments of the present disclosure, all of other embodiments that can be obtained by the skilled person in the art without any creative efforts also belong to the scope of the present disclosure.

Herein, the word “about” used along with a numerical value means that its numerical value may be in a numerical range, i.e., the value may be in a range of positive or negative 5%˜10% of a specific numerical value as listed.

Respective dimension and shape of each component in the drawings are only intended to exemplarily illustrate the contents of the disclosure, rather than to demonstrate the practical dimension or proportion of components of a display panel and a display device according to embodiments of the disclosure.

A relatively mainstream way in a relevant art for improving an adverse influence on a light extraction property of the OLED device as applied by the flexible encapsulating structure is to further provide a membrane layer of LiF additionally between the OLED device and a packaging/encapsulating portion for encapsulating the OLED device, the membrane layer of LiF being an inorganic membrane layer having a relatively lower refractive index, e.g., it may function to adjust an emergent light and to protect an organic membrane layer below itself in the OLED, so as to improve the light extraction property of the device effectively. However, the membrane layer of LiF has a relatively poorer toughness and thus may readily be broken off, and may readily absorb water/moisture to swell. As such, an existence of the membrane layer of LiF may for example easily incur phenomena such as peeling off of the membrane layer thereat, and crystallization in evaporation chamber there, and the like.

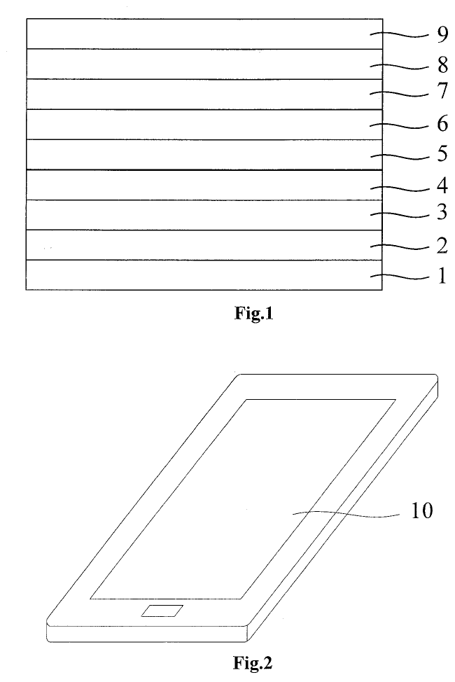

According to a general technical concept of the embodiments of the disclosure, as illustrated in FIG. 1, in an aspect of embodiments of the disclosure, a display panel is provided, comprising a base substrate 1; a light-emitting device on a side of the base substrate; and an encapsulating structure on a side of the light-emitting device facing away from the base substrate 1 and completely covering the light-emitting device, with an optical membrane layer 5 being provided between the encapsulating structure and the light-emitting device. The encapsulating structure comprises: a first inorganic encapsulating membrane 6 above the light-emitting device and on a side of the optical membrane layer 5 facing away from the base substrate 1, and a second inorganic encapsulating membrane 7 on a side of the first inorganic encapsulating membrane 6 facing away from the base substrate 1. The first inorganic encapsulating membrane 6 has a refractive index lower than that of the second inorganic encapsulating membrane 7 and that of the optical membrane layer 5; or alternatively, the first inorganic encapsulating membrane 6 has a refractive index higher than that of the second inorganic encapsulating membrane 7 and that of the optical membrane layer 5.

In some specific implementations, for example, in a display panel as above which functions as a flexible display panel, the light-emitting device, the optical membrane layer 5 and the encapsulating structure are provided in sequence above the base substrate 1 in a direction facing away from the base substrate. Wherein, the encapsulating structure comprises the first inorganic encapsulating membrane 6 disposed above the light-emitting device and on a side of the optical membrane layer 5 facing away from the base substrate 1, and a second inorganic encapsulating membrane 7 disposed on a side of the first inorganic encapsulating membrane 6 facing away from the base substrate 1; and the first inorganic encapsulating membrane 6 has a refractive index lower than that of the second inorganic encapsulating membrane 7 and that of the optical membrane layer 5, i.e., the optical membrane layer 5 having a relatively high refractive index, the first inorganic encapsulating membrane 6 having a relatively low refractive index, and the second inorganic encapsulating membrane 7 having a relatively high refractive index are formed on a light-emergent side of the light-emitting device. In other words, above all, the first inorganic encapsulating membrane 6 interposed between the optical membrane layer 5 and the second inorganic encapsulating membrane 7 possesses its refractive index lower than respective refractive indices of materials located at both sides thereof. By a stacked setting in a structure of three layers of membranes having a ‘high-low-high’ distribution of respective refractive indices, it ensures that an overall light extraction efficiency of the flexible display panel may not be decreased excessively due to the membrane packaging/encapsulating manner as applied on the light-emitting device and a possible existence of a single inorganic membrane layer which has a relatively low uniform refractive index and would have abutted closely and tightly against the encapsulating structure of this membrane packaging/encapsulating type. Furthermore, since the first inorganic encapsulating membrane 6 is a portion of the encapsulating structure set to abut against the optical membrane layer 5, i.e., by providing the first inorganic encapsulating membrane 6 within the encapsulating structure, which first inorganic encapsulating membrane 6 directly abuts against the optical membrane layer 5, then, a contact area between the first inorganic encapsulating membrane 6 and the optical membrane layer 5 is increased accordingly, such that an adhesive strength between the encapsulating structure and the optical membrane layer 5 is increased by the first inorganic encapsulating membrane 6 as added, avoiding occurrence of a peeling-off phenomenon between the encapsulating structure and the optical membrane layer 5. In addition, by providing the first inorganic encapsulating membrane 6, it also avoids a problem of crystallization in evaporation chamber which is caused by a direct contact at an interface between the encapsulating structure in relevant art which for example fails to have the first inorganic encapsulating membrane 6 as above and the optical membrane layer 5 (such as LiF membrane layer and the like), enhancing production efficiency, and decreasing production cost thereof.

In some other specific implementations, for example, in a display panel as above which functions as a flexible display panel, the light-emitting device, the optical membrane layer 5 and the encapsulating structure are provided in sequence above the base substrate 1 in a direction facing away from the base substrate. Wherein, the encapsulating structure comprises the first inorganic encapsulating membrane 6 disposed above the light-emitting device and on a side of the optical membrane layer 5 facing away from the base substrate 1, and a second inorganic encapsulating membrane 7 disposed on a side of the first inorganic encapsulating membrane 6 facing away from the base substrate 1; and the first inorganic encapsulating membrane 6 has a refractive index higher than that of the second inorganic encapsulating membrane 7 and that of the optical membrane layer 5, i.e., the optical membrane layer 5 having a relatively low refractive index, the first inorganic encapsulating membrane 6 having a relatively high refractive index, and the second inorganic encapsulating membrane 7 having a relatively low refractive index are formed on the light-emergent side of the light-emitting device. In other words, above all, the first inorganic encapsulating membrane 6 interposed between the optical membrane layer 5 and the second inorganic encapsulating membrane 7 possesses its refractive index higher than respective refractive indices of materials located at both sides thereof. By a stacked setting in a structure of three layers of membranes having a low-high-low′ distribution of respective refractive indices, it ensures that an overall light extraction efficiency of the flexible display panel may not be decreased excessively due to the membrane packaging/encapsulating manner as applied on the light-emitting device and a possible existence of a single inorganic membrane layer which has a relatively low uniform refractive index and would have abutted closely and tightly against the encapsulating structure of this membrane packaging/encapsulating type. Furthermore, since the first inorganic encapsulating membrane 6 is a portion of the encapsulating structure set to abut against the optical membrane layer 5, i.e., by providing the first inorganic encapsulating membrane 6 within the encapsulating structure, which first inorganic encapsulating membrane 6 directly abuts against the optical membrane layer 5, then, a contact area between the first inorganic encapsulating membrane 6 and the optical membrane layer 5 is increased accordingly, such that an adhesive strength between the encapsulating structure and the optical membrane layer 5 is increased by the first inorganic encapsulating membrane 6 as added, avoiding occurrence of the peeling-off phenomenon between the encapsulating structure and the optical membrane layer 5. In addition, by providing the first inorganic encapsulating membrane 6, it also avoids a problem of crystallization in evaporation chamber which is caused by a direct contact at an interface between the encapsulating structure in relevant art which for example fails to have the first inorganic encapsulating membrane 6 as above and the optical membrane layer 5 (such as LiF membrane layer and the like), enhancing production efficiency, and decreasing production cost thereof.

Therefore, in the flexible display panel as above, by preparing the first inorganic encapsulating membrane 6 having a relatively low refractive index, the second inorganic encapsulating membrane 7 having a relatively high refractive index sequentially on the optical membrane layer 5, and both the first inorganic encapsulating membrane 6 and the second inorganic encapsulating membrane 7 cooperate with each other to collectively function as the encapsulating structure, ensuring that an overall light extraction efficiency of the flexible display panel may not be decreased excessively due to the membrane packaging/encapsulating manner as applied on the light-emitting device and a possible existence of a single inorganic membrane layer which has a relatively low uniform refractive index and would have abutted closely and tightly against the encapsulating structure of this membrane packaging/encapsulating type, while increasing the adhesive strength between the encapsulating structure and the first inorganic encapsulating membrane 6 and in turn avoiding occurrence of the peeling-off phenomenon therebetween, and also avoiding occurrence of the problem of crystallization in evaporation chamber, thus enhancing production efficiency, and decreasing production cost thereof.

In an implementation of the first inorganic encapsulating membrane 6, for example, the refractive index of the first inorganic encapsulating membrane 6 ranges between 1.4 and 1.6.

Specifically, by way of example, the refractive index of the first inorganic encapsulating membrane 6 is 1.5.

Correspondingly, for example, in an implementation of the second inorganic encapsulating membrane 7, the refractive index of the second inorganic encapsulating membrane 7 ranges between 1.75 and 1.9.

Specifically, by way of example, the refractive index of the second inorganic encapsulating membrane 7 is one of 1.75, 1.8 and 1.9. In this embodiment, the refractive index of the second inorganic encapsulating membrane 7 is for example 1.9.

However, embodiments may not be limited hereto, and any other embodiments may be applicable as long as a condition in which the refractive index of the first inorganic encapsulating membrane 6 is smaller than the refractive index of the second inorganic encapsulating membrane 7 is satisfied. And in this embodiment, the larger a difference between the refractive index of the first inorganic encapsulating membrane 6 and the refractive index of the second inorganic encapsulating membrane 7 is, i.e., the more significant a degree that the refractive index of the first inorganic encapsulating membrane 6 mismatches the refractive index of the second inorganic encapsulating membrane 7 (i.e., a degree that the refractive index of the first inorganic encapsulating membrane 6 is not similar to the refractive index of the second inorganic encapsulating membrane 7) is, then the higher the light extraction efficiency of the flexible display panel is.

In an embodiment, the first inorganic encapsulating membrane 6 is for example formed by a material comprising SiOx, i.e., an oxide of the element Si. Specifically, the first inorganic encapsulating membrane is for example formed by SiO₂.

In an implementation of the first inorganic encapsulating membrane 6 as above, the first inorganic encapsulating membrane 6 has its thickness ranging between 40 nm and 120 nm.

Specifically, by way of example, the thickness of the first inorganic encapsulating membrane 6 is for example 40 nm, or 60 nm, or 80 nm, or 100 nm, or 120 nm; and a practical value of the thickness of the first inorganic encapsulating membrane 6 may be specifically determined depending on expected size of the flexible display panel and other design requirements.

In this embodiment, the second inorganic encapsulating membrane 7 is for example formed by a material comprising SiNxOy. As such, the second inorganic encapsulating membrane 7 formed by SiNxOy and the first inorganic encapsulating membrane 6 formed by SiOx are stacked over each other, such that there is a relatively large adhesive force existing between the first inorganic encapsulating membrane 6 and the second inorganic encapsulating membrane 7, ensuring a stability and robustness of a connection between the first inorganic encapsulating membrane 6 and the second inorganic encapsulating membrane 7, and in turn increasing the stability of the encapsulating structure.

Specifically, the second inorganic encapsulating membrane 7 for example has a thickness which is chosen in a range between 800 nm and 1000 nm.

The thickness of the second inorganic encapsulating membrane 7 is for example 800 nm, or 850 nm, or 900 nm, or 950 nm, or 1000 nm, without being defined herein in embodiments; and the thickness of the second inorganic encapsulating membrane 7 is chosen depending on an expected size of the flexible display panel.

And specifically, for example, in a condition that the refractive index of the first inorganic encapsulating membrane 6 is lower than the refractive index of the second inorganic encapsulating membrane 7 and the refractive index of the optical membrane layer 5, for example, the refractive index of the second inorganic encapsulating membrane 7 is larger than or equal to the refractive index of the optical membrane layer 5.

Or alternatively, specifically, for example, in a condition that the refractive index of the first inorganic encapsulating membrane 6 is higher than the refractive index of the second inorganic encapsulating membrane 7 and the refractive index of the optical membrane layer 5, for example, the refractive index of the second inorganic encapsulating membrane 7 is smaller than or equal to the refractive index of the optical membrane layer 5.

In an implementation of the encapsulating structure as above, for example, the encapsulating structure further comprises: an organic encapsulating membrane 8 located on a side of the second inorganic encapsulating membrane 7 facing away from the base substrate 1; and a third inorganic encapsulating membrane 9 located on a side of the organic encapsulating membrane 8 facing away from the base substrate 1.

In above encapsulating structure, the first inorganic encapsulating membrane 6, the second inorganic encapsulating membrane 7 and the third inorganic encapsulating membrane 9 in the encapsulating structure cooperate with one another to obstruct/block a major of ambient moisture outside the light emitting device which is encapsulated by the encapsulating structure, enhancing an encapsulating effect applied on the light emitting device by the encapsulating structure. And by providing the organic encapsulating membrane 8 additionally between the second inorganic encapsulating membrane 7 and the third inorganic encapsulating membrane 9, then the encapsulating structure having a ‘inorganic-organic-inorganic’ stacked structure is formed; as such, by a bond between the organic membrane layer and inorganic membrane layers, mechanical properties of the encapsulating structure is efficiently enhanced, implementing a compromise among properties of tightness/sealing property, firmness, and toughness of the encapsulating structure, and in turn improving encapsulating property, preventing water/moisture and oxygen from entering the light emitting device, and improving service life of the flexible display panel.

In an implementation of the light emitting device as above, the light emitting device comprises an anode layer 2 above the base substrate 1 and a cathode layer 4 above the anode layer 2, and an organic light emitting material layer 3 interposed between the anode layer 2 and the cathode layer 4.

In embodiments of the disclosure, by providing the optical membrane layer 5 having a relatively high refractive index, the first inorganic encapsulating membrane 6 having a relatively low refractive index, the second inorganic encapsulating membrane 7 having a relatively high refractive index which are stacked in sequence above the light emitting device, it ensures that the overall light extraction efficiency of the flexible display device may not be decreased excessively due to the membrane packaging/encapsulating manner as applied on the light-emitting device and a possible existence of a single inorganic membrane layer which has a relatively low uniform refractive index and would have abutted closely and tightly against the encapsulating structure of this membrane packaging/encapsulating type. And the larger a difference between the refractive index of one membrane layer having a relatively low refractive index and that of another membrane layer having a relatively high refractive index is, i.e., the more significant a degree that respective refractive indices of both mismatch each other (i.e., a degree that respective refractive indices of both are not similar to each other) is, then the higher the light extraction efficiency of the flexible display panel is.

In another embodiment, in a condition that respective refractive indices of both the optical membrane layer 5 and the second inorganic encapsulating membrane 7 are lower than the refractive index of the first inorganic encapsulating membrane 6 interposed therebetween, i.e., in a condition that the optical membrane layer 5 having a relatively low refractive index, the first inorganic encapsulating membrane 6 having a relatively high refractive index, the second inorganic encapsulating membrane 7 having a relatively low refractive index which are stacked in sequence above the light emitting device, it ensures that the overall light extraction efficiency of the flexible display device may not be decreased excessively due to the membrane packaging/encapsulating manner as applied on the light-emitting device and a possible existence of a single inorganic membrane layer which has a relatively low uniform refractive index and would have abutted closely and tightly against the encapsulating structure of this membrane packaging/encapsulating type. And the larger a difference between the refractive index of one membrane layer having a relatively low refractive index and that of another membrane layer having a relatively high refractive index is, i.e., the more significant a degree that respective refractive indices of both mismatch each other (i.e., a degree that respective refractive indices of both are not similar to each other) is, then the higher the light extraction efficiency of the flexible display panel is.

As illustrated in FIG. 2, according to another aspect of embodiments of the disclosure, based on the inventive concept of aforementioned embodiments, a display device is further provided in embodiments of the disclosure, comprising any one of flexible display panels 10 as provided in technical solutions of embodiments as above.

As compared with relevant art, embodiments of the disclosure have beneficial effects as below:

A flexible display panel and a display device are provided in embodiments of the disclosure. In above flexible display panel, the light-emitting device, the optical membrane layer and the encapsulating structure are provided in sequence above the base substrate in a direction facing away from the base substrate. Wherein, the encapsulating structure comprises the first inorganic encapsulating membrane disposed above the light-emitting device and on a side of the optical membrane layer facing away from the base substrate, and a second inorganic encapsulating membrane disposed on a side of the first inorganic encapsulating membrane facing away from the base substrate. And the first inorganic encapsulating membrane has a refractive index lower than that of the second inorganic encapsulating membrane and that of the optical membrane layer, i.e., the optical membrane layer having a relatively high refractive index, the first inorganic encapsulating membrane having a relatively low refractive index, and the second inorganic encapsulating membrane having a relatively high refractive index are formed on a light-emergent side of the light-emitting device. Or alternatively, the first inorganic encapsulating membrane has a refractive index higher than that of the second inorganic encapsulating membrane and that of the optical membrane layer, i.e., the optical membrane layer having a relatively low refractive index, the first inorganic encapsulating membrane having a relatively high refractive index, and the second inorganic encapsulating membrane having a relatively low refractive index are formed on the light-emergent side of the light-emitting device. To sum up, by a stacked setting in a structure of three layers of membranes having a ‘high-low-high’ or low-high-low′ distribution of respective refractive indices, it ensures that the overall light extraction efficiency of the flexible display panel may not be decreased excessively due to the membrane packaging/encapsulating manner as applied on the light-emitting device and a possible existence of a single inorganic membrane layer which has a relatively low uniform refractive index and would have abutted closely and tightly against the encapsulating structure of this membrane packaging/encapsulating type. Furthermore, since the first inorganic encapsulating membrane is a portion of the encapsulating structure set to abut against the optical membrane layer, i.e., by providing the first inorganic encapsulating membrane 6 within the encapsulating structure, which first inorganic encapsulating membrane 6 directly abuts against the optical membrane layer, then, within the encapsulating structure, a contact area between the first inorganic encapsulating membrane and the optical membrane layer is increased accordingly, such that an adhesive strength between the encapsulating structure and the optical membrane layer is increased by the first inorganic encapsulating membrane as added, avoiding occurrence of the peeling-off phenomenon between the encapsulating structure and the optical membrane layer. In addition, by providing the first inorganic encapsulating membrane, it also avoids a problem of crystallization in evaporation chamber which is caused by a direct contact at an interface between the encapsulating structure in relevant art which for example fails to have the first inorganic encapsulating membrane as above and the optical membrane layer 5 (such as LiF membrane layer and the like), enhancing production efficiency, and decreasing production cost thereof.

Therefore, in the flexible display panel as above, by preparing the first inorganic encapsulating membrane and the second inorganic encapsulating membrane on the optical membrane layer, then it ensures the light extraction efficiency and also improves the adhesive strength between the optical membrane layer and the encapsulating structure and avoids the peeling-off phenomenon between or among membrane layers; at the same time, it also avoids the problem of crystallization in evaporation chamber, enhancing production efficiency, and decreasing production cost thereof.

Apparently, those skilled in the art may make various modifications and variations on embodiments of the disclosure, without departing from the spirit and scope of the present disclosure. As such, all these modifications and variations on embodiments of the disclosure may fall within the scope of the present disclosure is defined by the appended claims or equivalents thereof, and embodiments of the disclosure also intend to contain these modifications and variations.

What is claimed is:

1. A display panel, comprising:
a base substrate;
a light-emitting device on the base substrate; and
an encapsulating structure on a side of the light-emitting device facing away from the base substrate and completely covering the light-emitting device,
wherein an optical membrane layer is provided between the encapsulating structure and the light-emitting device;
the encapsulating structure comprises: a first inorganic encapsulating membrane above the light-emitting device and on a side of the optical membrane layer facing away from the base substrate, and a second inorganic encapsulating membrane on a side of the first inorganic encapsulating membrane facing away from the base substrate; and
the first inorganic encapsulating membrane has a refractive index lower than that of the second inorganic encapsulating membrane and that of the optical membrane layer; or the first inorganic encapsulating membrane has a refractive index higher than that of the second inorganic encapsulating membrane and that of the optical membrane layer.

2. The display panel according to claim 1, wherein the refractive index of the first inorganic encapsulating membrane ranges between about 1.4 and about 1.6.

3. The display panel according to claim 2, wherein the first inorganic encapsulating membrane is formed by a material comprising SiOx.

4. The display panel according to claim 3, wherein the first inorganic encapsulating membrane has a thickness ranging between about 40 nm and about 120 nm.

5. The display panel according to claim 1, wherein the refractive index of the second inorganic encapsulating membrane ranges between about 1.75 and about 1.9.

6. The display panel according to claim 5, wherein the second inorganic encapsulating membrane is formed by a material comprising SiNxOy.

7. The display panel according to claim 6, wherein the second inorganic encapsulating membrane has a thickness ranging between about 800 nm and about 1000 nm.

8. The display panel according to claim 1, wherein in response to a condition that the first inorganic encapsulating membrane has its refractive index lower than that of the second inorganic encapsulating membrane and that of the optical membrane layer, the refractive index of the second inorganic encapsulating membrane is larger than or equal to the refractive index of the optical membrane layer.

9. The display panel according to claim 1, wherein in response to a condition that the first inorganic encapsulating membrane has its refractive index higher than that of the second inorganic encapsulating membrane and that of the optical membrane layer, the refractive index of the second inorganic encapsulating membrane is smaller than or equal to the refractive index of the optical membrane layer.

10. The display panel according to claim 1, wherein the encapsulating structure further comprises:
an organic encapsulating membrane on a side of the second inorganic encapsulating membrane facing away from the base substrate; and
a third inorganic encapsulating membrane on a side of the organic encapsulating membrane facing away from the base substrate.

11. A display device, comprising the display panel according to claim 1.

12. A display device, comprising the display panel according to claim 2.

13. A display device, comprising the display panel according to claim 3.

14. A display device, comprising the display panel according to claim 4.

15. A display device, comprising the display panel according to claim 5.

16. A display device, comprising the display panel according to claim 6.

17. A display device, comprising the display panel according to claim 7.

18. A display device, comprising the display panel according to claim 8.

19. A display device, comprising the display panel according to claim 9.

20. A display device, comprising the display panel according to claim 10.
